(19) United States
(12) Patent Application Publication
(10) Pub. No.: US 2012/0107506 A1
(43) Pub. Date: May 3, 2012

(54) FILM FORMATION METHOD AND FILM FORMATION APPARATUS

(75) Inventors: Nobutaka Ukigaya, Mobara-shi (JP); Masamichi Masuda, Mobara-shi (JP); Yoshiyuki Nakagawa, Chiba-shi (JP); Masanori Yoshida, Chiba-shi (JP)

(73) Assignee: CANON KABUSHIKI KAISHA, Tokyo (JP)

(21) Appl. No.: 13/270,551

(22) Filed: Oct. 11, 2011

(30) Foreign Application Priority Data
Oct. 27, 2010 (JP) 2010-240759

(51) Int. Cl. B05D 1/32; B05C 13/02

(52) U.S. Cl. 427/272; 118/500

(57) ABSTRACT

Provided is a film formation apparatus capable of causing a substrate and a mask to be in a substantially horizontal state and brought into intimate contact with each other without deforming mask apertures. A region inside a mask frame and outside aperture regions of a mask on a rear surface of a substrate is pressed by a pressing body in lines along two opposing sides of the substrate.

### BACKGROUND OF THE INVENTION

1. Field of the Invention

The present invention relates to a film formation method and a film formation apparatus for forming a predetermined thin film pattern on a substrate according to an aperture pattern of a mask which is placed so as to be in intimate contact with a front surface of the substrate.

2. Description of the Related Art

Conventionally, in a manufacturing process of an organic electroluminescent (EL) thin film, a mask film formation method is often employed in which a mask having a predetermined aperture pattern is placed so as to be in intimate contact with a glass substrate when a film is formed. A known example of the mask film formation method is the following mask evaporation method.

The mask evaporation method is a method in which a substrate front surface (surface on which a film is to be formed) is placed downward, and an evaporation material evaporated from an evaporation source placed so as to be opposed to the substrate front surface is evaporated onto the substrate front surface via a mask, thereby forming a predetermined organic EL thin film on the substrate front surface. When such organic EL thin film is used as a color display panel, in order to form a thin film pattern having pitches similar to those of pixels in the display panel, a mask having apertures corresponding to the pattern is used. Pixel pitches of a display panel are several tens of micrometers, and pixels of three colors, i.e., red, green, and blue are regularly placed, and thus, the mask apertures are formed so as to correspond thereto. For example, with regard to the shape of the mask apertures, a slit-like shape in which the slit ranges multiple pixels or a dot-like shape in which the dot-like aperture is provided in each pixel is used.

In recent years, the resolution of an organic EL panel becomes higher and higher, and the pixel pitches become finer and finer accordingly, which requires the mask apertures to become finer. When the thickness of the mask is relatively large (0.5 mm to 1.0 mm), portions in the mask apertures near the evaporation pattern are shaded with the mask, which causes the film thickness at the portions to be smaller than that of center portions in the mask apertures. In order to reduce or eliminate nonuniformity due to such a film thickness distribution (edge blur), it is better that the mask is as thin as possible. For example, thin masks having thicknesses of 0.01 mm to 0.4 mm are used. Meanwhile, a substrate on which an organic EL thin film is to be formed becomes larger and larger. For use in a large flat panel display, a substrate with the size of, for example, about 370 mm×470 mm or larger becomes available.

On the other hand, in the above-mentioned evaporation method for forming an organic EL thin film, both the mask and the substrate warp, the extent of which differs, and thus, a gap is liable to occur between the mask and the substrate. In particular, in a large-sized substrate, the difference in deflection between the mask and the substrate becomes larger, and the gap caused between the mask and the substrate becomes as large as several tens of micrometers or more (which is close to the pixel pitches or the mask aperture width). When a gap is caused between the mask and the substrate in this way, the evaporation material enters the gap to blur the edges of the evaporation pattern, resulting in a vague evaporation pattern. Therefore, there are problems that the evaporation accuracy is lowered and that the evaporation material enters an adjacent pixel to cause failure.

Therefore, as disclosed in Japanese Patent Application Laid-Open No. H11-158605, a vacuum film formation apparatus is known in which a mask formed of a magnetic material is attached to a substrate front surface and the mask is brought into intimate contact with the substrate front surface in a horizontal state by magnetic attraction caused by a magnet holder provided on a rear surface side of the substrate.

However, when the substrate and the mask are brought into intimate contact with each other using only magnetic attraction of a magnet, the following problems occur. A mask aperture for forming an evaporation pattern which corresponds to pixels of an organic EL panel has a problem that the shape thereof is deformed when a magnet approaches, and thus, a predetermined thin film pattern may not be formed. The reason for this is, when the mask is to be attracted by magnetic force, it is necessary that the mask contain a ferromagnetic metal such as Fe, Ni, or Co as a mask formed of a magnetic material. Such ferromagnetic metal is liable to be magnetized and, in the ferromagnetic metal, correspondingly to an applied magnetic field of the magnet, force (for example, repulsive force) acts between fine mask patterns. As a result, deformation is caused to locally widen or narrow the mask aperture. Further, such deformation of the mask aperture results in abnormal display in the organic EL panel due to a pixel defect, a line defect, or the like. In particular, while the weight of the substrate itself becomes heavier as the size becomes larger, when a mask which is thinned to respond to higher resolution of the display panel is used, an intense magnet is necessary in order to pull up the thin mask from a rear surface of the substrate and to hold the mask in intimate contact with the substrate. Therefore, the problem of the deformation of the mask apertures becomes more liable to occur.

### SUMMARY OF THE INVENTION

Accordingly, an object of the present invention is to provide a film formation apparatus capable of causing a substrate and a mask to be in intimate contact with each other in a substantially horizontal state without deforming mask apertures as described above, and also provide a film formation method using the film formation apparatus.

According to a first aspect of the present invention, there is provided a method for forming a film on a substrate surface on which a film is to be formed, via a mask including therein multiple apertures, in a manner that the mask is fixed to a mask frame under tension at least in one direction and the mask is brought into intimate contact with the substrate surface on which a film is to be formed, the substrate being placed above the mask, the method including pressing the substrate from a rear surface side of the substrate in lines along at least two opposing sides of the substrate at least in a region inside the mask frame.

According to a second aspect of the present invention, there is provided a film formation apparatus including: a mask frame for fixing thereto a mask under tension; a substrate support member for holding a substrate above the mask, with a substrate surface on which a film is to be formed facing on the mask; and a pressing body for pressing the substrate from a rear surface side in lines along at least two opposing sides of the substrate at least in a region inside the mask frame.

According to the present invention, the mask and the substrate may be brought into intimate contact with each other in a substantially horizontal state without deforming the mask apertures. Therefore, a thin film pattern may be formed according to a predetermined mask aperture pattern. Further, a high-quality thin film pattern may be obtained which has no edge blur and the like caused by an evaporation material that enters through a gap between the mask and the substrate.

Further features of the present invention will become apparent from the following description of exemplary embodiments with reference to the attached drawings.

### BRIEF DESCRIPTION OF THE DRAWINGS

FIG. 1 is a sectional view schematically illustrating the positional relationship among a substrate, a mask, and a pressing body in one embodiment of a film formation apparatus according to the present invention.

FIG. 2 is a sectional view schematically illustrating a state in which the substrate and the mask are brought into intimate contact with each other in the one embodiment of the film formation apparatus according to the present invention.

FIG. 3 is a sectional view schematically illustrating a state in which the pressing body presses a rear surface of the substrate in the one embodiment of the film formation apparatus according to the present invention.

FIG. 4 is a sectional view schematically illustrating the positional relationship among the substrate, the mask, and the pressing body in another embodiment of the film formation apparatus according to the present invention.

FIG. 5 is an exploded perspective view schematically illustrating the positional relationship among the substrate, the mask, and the pressing body in the one embodiment of the film formation apparatus according to the present invention.

FIG. 6 is a plan view schematically illustrating positions at which the pressing body presses in the one embodiment of the film formation apparatus according to the present invention.

FIG. 7 is a plan view schematically illustrating positions at which the pressing body presses in another embodiment of the film formation apparatus according to the present invention.

FIG. 8 is a plan view schematically illustrating positions at which the pressing body presses in still another embodiment of the film formation apparatus according to the present invention.

FIG. 9 is a plan view schematically illustrating positions at which the pressing body presses in yet another embodiment of the film formation apparatus according to the present invention.

FIG. 10 is a plan view schematically illustrating positions at which the pressing body presses in still another embodiment of the film formation apparatus according to the present invention.

FIG. 11 is a plan view schematically illustrating positions at which the pressing body presses in yet another embodiment of the film formation apparatus according to the present invention.

FIG. 12 is a plan view schematically illustrating positions at which the pressing body presses in still another embodiment of the film formation apparatus according to the present invention.

### DESCRIPTION OF THE EMBODIMENTS

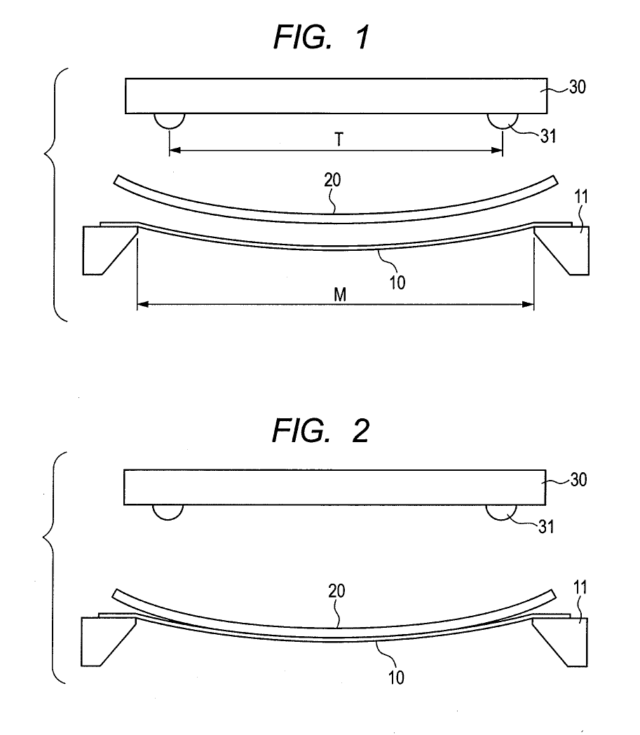

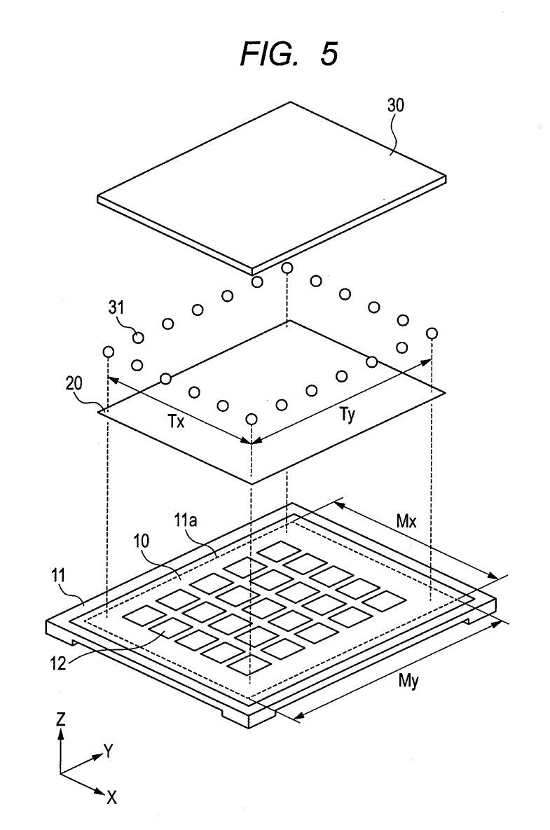

The present invention is described in the following based on embodiments illustrated in the attached drawings. FIGS. 1 to 3 are schematic sectional views for illustrating a film formation method and a film formation apparatus according to an embodiment of the present invention, and illustrate the positional relationship among a substrate, a mask, and a pressing body in the film formation apparatus. FIG. 5 is an exploded perspective view corresponding to FIG. 1. In this embodiment, a case is described in which an organic EL thin film is formed by evaporation on a front surface of a glass substrate.

A mask holder (not shown), which is located in an evaporation apparatus for holding a mask 10 and a mask frame 11, is coupled to a mask position controller (not shown). By driving the mask position controller, movement of the mask held by the mask holder in directions of the X axis and the Y axis and rotation of the mask about the Z axis may be controlled independently. Note that, the mask as used in the present invention includes multiple predetermined apertures and is, under tension in at least one direction, fixed to the rectangular, rigid mask frame 11. The tension on the mask 10 is at least in a direction along two opposing sides of a substrate 20, and is, ordinarily, at least in a long side direction of the mask apertures.

Further, a substrate support member (not shown) for supporting the substrate 20 is coupled to a substrate position controller (not shown). By driving the substrate position controller, movement of the substrate 20 supported by the substrate support member in the directions of the X axis and the Y axis and rotation of the substrate 20 about the Z axis may be controlled independently.

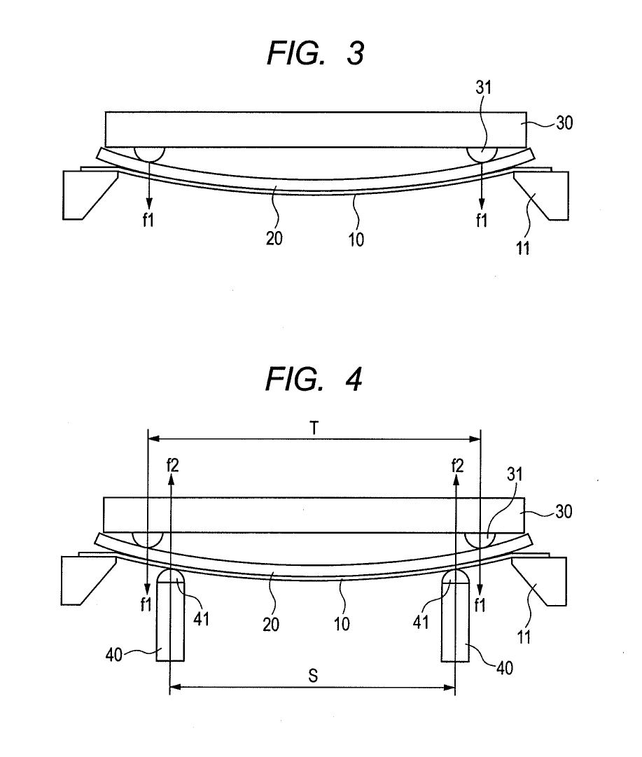

As illustrated in FIG. 1, multiple ball-like bodies 31 are attached to a flat surface of a pressing body 30 on the substrate 20 side so as to protrude therefrom. The pressing body 30 is used for bringing the substrate 20 and the mask 10 into intimate contact with each other. The ball-like bodies 31 are members for applying necessary external force to the substrate 20 by direct contact therewith. In a state as illustrated in FIG. 3 in which the pressing body 30 is moved so that the ball-like bodies 31 press a rear surface of the substrate 20, the ball-like bodies 31 pressing the substrate 20 are positioned in a region inside the mask frame 11 defined by a broken line 11a. In other words, a width M of the region inside the mask frame 11 illustrated in FIG. 1 and a distance T between ball-like bodies 31 placed along two opposing sides are in the relationship of M>T.

FIG. 5 is an exploded perspective view of this embodiment. The multiple ball-like bodies 31 placed in lines along the four sides of the substrate 20 are placed in the vicinity of the mask frame 11. Note that, the vicinity of the mask frame 11 means a region which is ¼ of the width of the region inside the mask frame 11 (M in the figures) from the mask frame 11 toward the center of the mask 10. Further, with regard to the X direction and the Y direction in the figures, widths Mx and My of the region inside the mask frame 11 and distances Tx and Ty between ball-like bodies 31 placed along two opposing sides are in the relationship of Mx>Tx and My>Ty, respectively. Note that, in FIG. 5, for the sake of convenience, the ball-like bodies 31 are illustrated in a state of being detached from the pressing body 30. Aperture regions 12 of the mask 10 are illustrated in FIG. 5 as 5×5=25 rectangular regions, but, in each of the regions, multiple fine apertures are formed in dots or stripes. In this embodiment, each of the aperture regions corresponds to one organic EL display device, and multiple, i.e., 5×5=25 organic EL display devices are formed at the same time.

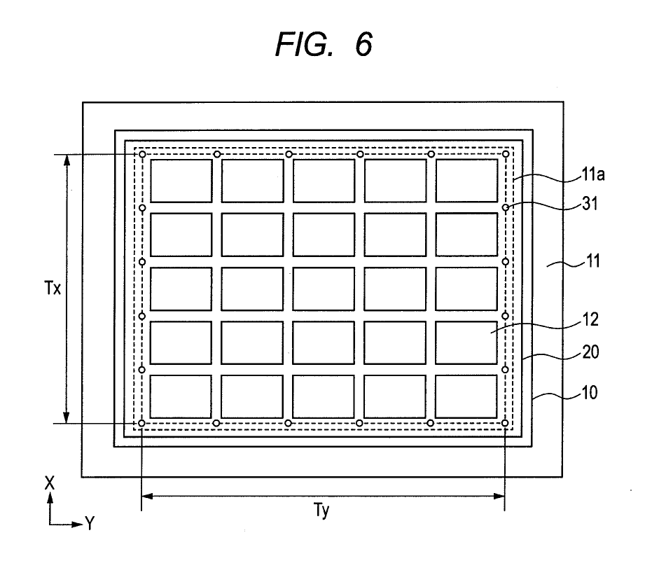

FIG. 6 is a schematic plan view illustrating pressing positions of the ball-like bodies 31 of the pressing body 30. In FIG. 6, like reference numerals are used to designate like or identical members illustrated in FIGS. 1 to 3. In particular, when the mask aperture pattern is fine, as illustrated in FIG. 6, it is desired that the positions at which the ball-like bodies 31 are brought into contact with the substrate 20 correspond to a non-aperture region which does not overlap the mask apertures. This may suppress the risk of deforming the fine mask apertures by the pressing.

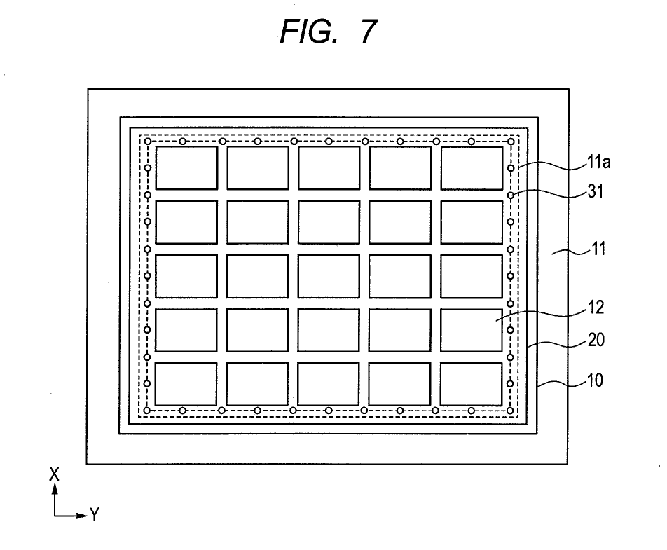

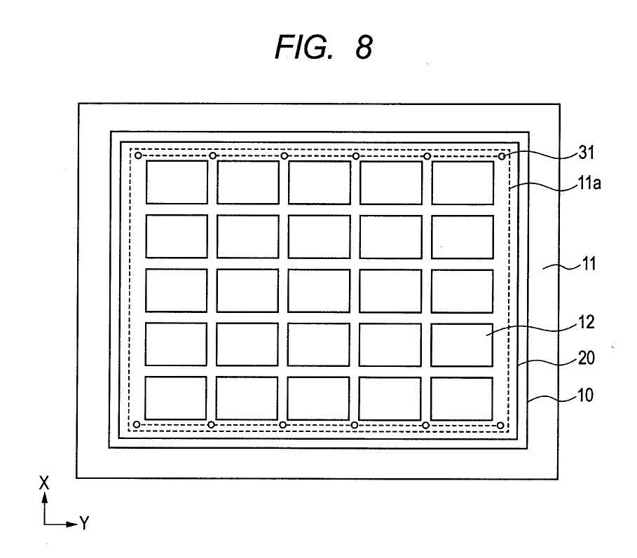

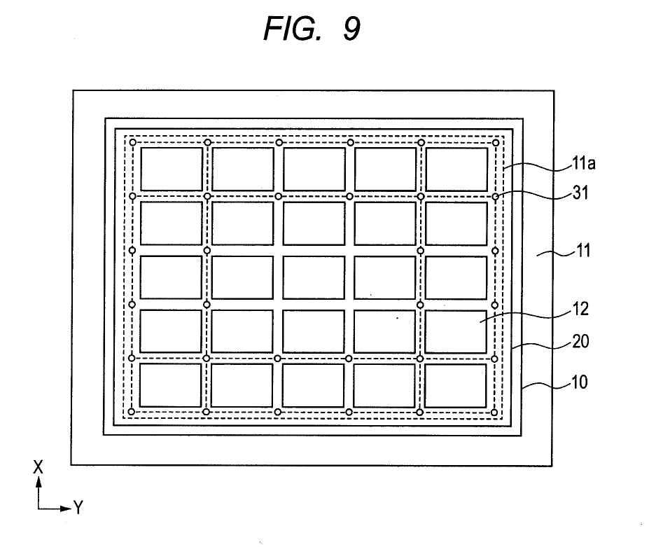

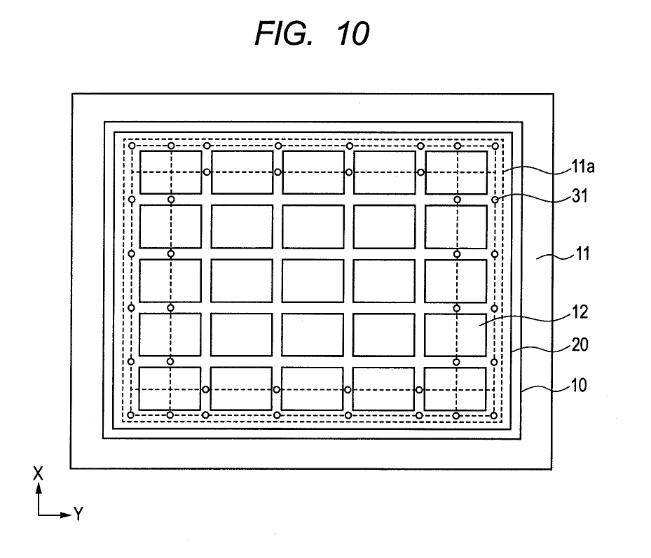

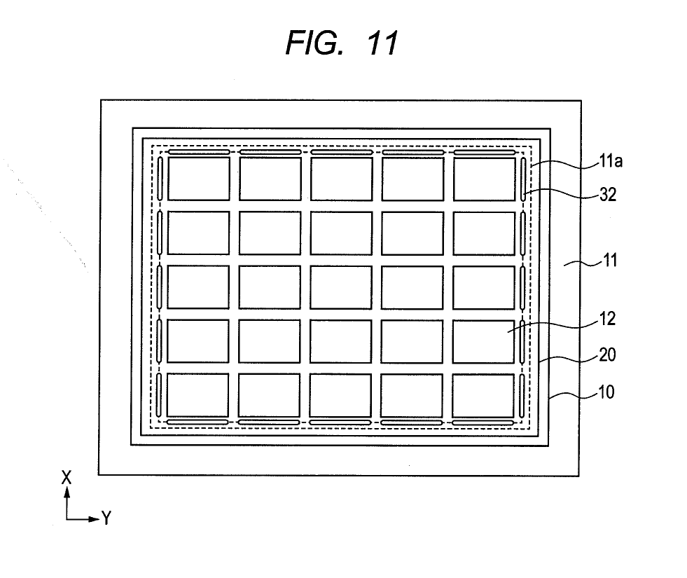

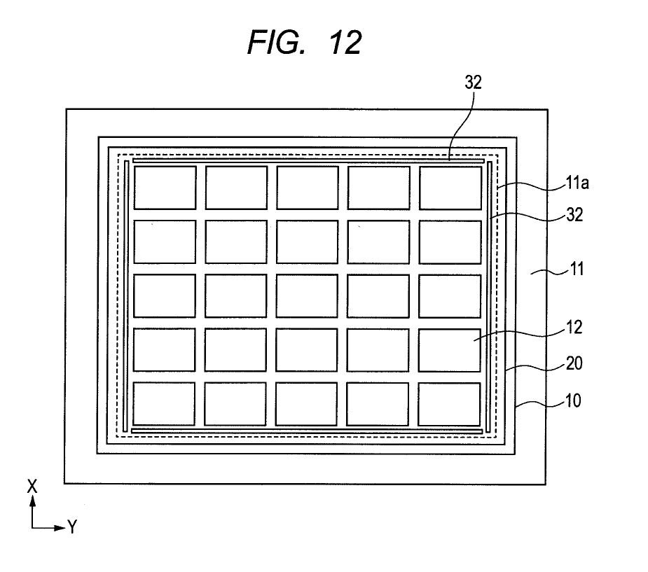

Note that, in the present invention, the positions at which the pressing body 30 presses the substrate 20 from the rear surface side thereof are in lines along at least two opposing sides of the substrate 20. The lines as used herein may be continuous or intermittent. Examples of the layout of the pressing positions of the pressing body 30 are illustrated in FIGS. 6 to 12. In FIG. 7, the pitches at which the ball-like bodies 31 are arranged are finer than those in FIG. 6. In FIG. 8, the ball-like bodies 31 are arranged along only two opposing sides of the substrate 20. In FIGS. 9 and 10, the ball-like bodies 31 are wound two turns in lines along the four sides of the substrate 20. Further, in FIGS. 11 and 12, the members to be brought into contact with the substrate 20 are rod-like structures 32 extending in directions of the sides of the substrate 20. Note that, which of the forms of the pressing body 30 is selected depends on, for example, the size of the actually used mask, the layout of the aperture pattern, the tension, and the size, thickness, deflection, and the like of the substrate 20, and an optimum combination to attain the intimate contact may be selected taking those into consideration. Further, a pressing force applied by the pressing body 30 to the substrate 20 may be appropriately adjusted.

Note that, it is desired that the ball-like bodies 31 placed on the pressing body 30 be rotatable. The reason is that, if the ball-like bodies 31 are rotatable, friction between the ball-like bodies 31 and the substrate 20 in the in-plane direction of the substrate 20 may be alleviated to prevent adverse effects on the positional accuracy between the substrate 20 and the mask 10 which is adjusted at a previous process step. Further, it is desired that, in the pressing body 30, the ball-like bodies 31 be combined with an elastic body so that force applied by the ball-like bodies 31 to the substrate 20 may be arbitrarily adjusted.

In the above-mentioned pressing body 30, the ball-like bodies 31 are described as exemplary members to be brought into contact with the substrate 20, but the present invention is not limited thereto. Any structure having a basic function capable of pressing a selected region may be employed, and it is desired that the structure have a curved surface which is to be brought into contact with the substrate 20 so as not to damage the substrate 20.

Further, in the above, the case in which the pressing body 30 is in contact with the substrate 20 at multiple points within the rear surface of the substrate 20 is described by way of example, but a ring-like structure may be used so that the pressing body 30 may be brought into contact with the substrate 20 in lines along the four sides thereof. Further, as a material of the members to be brought into contact with the substrate 20 (for example, the ball-like bodies 31), a metal, a resin, a glass, or the like may be appropriately used.

In the present invention, a more exemplary embodiment is a structure in which the pressing force applied to the rear surface of the substrate 20 in lines is larger in a direction perpendicular to the direction of maximum tension on the mask 10 than in a direction in parallel therewith. More specifically, referring to FIGS. 5 and 6, a case in which tension is applied on the mask 10 in the X direction or a case in which tension applied on the mask in the X direction is larger than that in the Y direction is described by way of example. In this case, the ball-like bodies 31 placed in lines along the Y direction apply a larger pressing force than the ball-like bodies 31 placed in lines along the X direction apply. This enables more uniform intimate contact of the whole mask 10 to the substrate 20. Note that, in this case, the ball-like bodies 31 for pressing the substrate 20 in lines along the X direction and the ball-like bodies 31 for pressing the substrate 20 in lines along the Y direction are separately structured so that the pressing forces thereof may be independently adjusted. Note that, the ratio of the pressing force along the X direction to the pressing force along the Y direction, which are necessary for the intimate contact, depends on the balance with reaction force on the substrate within the plane of the mask and with the reaction force distribution. Thus, the ratio depends on the ratio of the tension on the mask along the X direction to the tension on the mask along the Y direction, the layout of the mask aperture pattern, and the size of the aperture pattern. For example, when the ratio of the tensions on the mask (Y/X) is in a range of 0.5 to 0.9, it is preferred that the ratio of the pressing forces of the pressing body (Y/X) be in a range of 1.1 to 2.0.

Further, in this case, the ball-like bodies 31 for pressing the substrate 20 in lines along the X direction and the ball-like bodies 31 for pressing the substrate 20 in lines along the Y direction are separately structured so that the pressing forces thereof may be independently adjusted. Alternatively, the multiple ball-like bodies 31 arranged in the respective directions in lines may be separately structured so that the pressing forces thereof may be individually adjusted. In this case, adjustments according to the conditions of the deflection of the mask and the deflection of the substrate may also be made. This may avoid pressing with excess force, and thus, may avoid damage to the substrate and the mask.

Next, an evaporation method according to an embodiment of the present invention is described with reference to FIGS. 1 to 3. First, as a process step previous to evaporating the organic EL thin film on a front surface of the substrate 20, the mask 10 is aligned with the front surface of the substrate 20 and is brought into intimate contact therewith. More specifically, from the state illustrated in FIG. 1, a moving mechanism is driven to lower the substrate 20 supported by the substrate support member to approach the mask 10. Here, multiple CCD cameras (not shown) are used to recognize the images of respective alignment marks formed on the substrate 20 and the mask 10, and the substrate position controller coupled to the substrate support member is driven so that the positions of the alignment marks become in alignment. By the drive of the substrate position controller, the substrate 20 is moved in the directions of the X axis and the Y axis and is rotated about the Z axis so that misalignment between the alignment marks of the substrate 20 and the mask 10 is corrected to obtain predetermined accuracy. In this state, the mask 10 and the substrate 20 warp with their center portions being at the lowest level due to their own weights.

After the above-mentioned alignment is completed, the substrate 20 is further lowered toward the mask 10, and, as illustrated in FIG. 2, the front surface of the substrate 20 is brought into contact with the mask 10. After the contact, the multiple CCD cameras are used to measure the misalignment between the alignment marks of the substrate 20 and the mask 10, and confirm that the accuracy is in the predetermined range. In this state, the pressing body 30 stands still above the rear surface of the substrate 20, and hence the region in which the front surface of the substrate 20 is in intimate contact with the mask 10 without a gap is limited. In particular, in a large peripheral area of the substrate 20, a large gap of 10 μm to 100 μm is caused between the substrate 20 and the mask 10.

After that, as illustrated in FIG. 3, the pressing body 30 is lowered to be brought into contact with the rear surface of the substrate 20. Here, the ball-like bodies 31, which protrude from the pressing body 30 toward the substrate 20, press the rear surface of the substrate along the four sides of the rear surface of the substrate 20. The locations at which the substrate 20 is pressed are set in the region inside the mask frame 11, and thus, a downward force acts not only on the substrate 20 but also on the mask 10. Therefore, with the substrate 20 being mounted on the mask 10 which is fixed to the mask frame 11 under tension, the downward force applied by the ball-like bodies 31 provided along the four sides of the substrate 20 generates a reaction force in the substrate 20 and in the mask 10. The reaction force acts as a force to lift up the substrate 20 and the mask 10 in a range from the vicinity of the pressed positions of the substrate 20 to the center of the substrate 20. The center portions of the substrate 20 and the mask 10 are similarly lifted up by the reaction force. This reduces or eliminates the deflection of the center portions of the substrate 20 and the mask 10, and may cause both the substrate 20 and the mask 10 to be in a substantially horizontal state. More specifically, an external force against the reaction force of the mask 10 acting on the substrate 20 is applied in the region inside the mask frame 11 in lines along the respective sides of the substrate 20, to thereby cause the substrate 20 and the mask 10 in a horizontal state in a wide range.

Therefore, according to the present invention, the substrate 20 and the mask 10 may be brought into intimate contact with each other in a wide range without a gap and without deforming the fine mask aperture pattern. Further, even when the size of the substrate 20 used is large, deflection of the center portion thereof due to its own weight may be suppressed to maintain the horizontal state by the method described above, and thus, the substrate 20 and the mask 10 may be brought into intimate contact with each other in a wide range without a gap.

Further, according to the present invention, there is exemplified another configuration in which a support body supports the substrate 20 from the side of the surface of the substrate 20 on which a film is to be formed. FIG. 4 schematically illustrates this state. As illustrated in FIG. 4, a support body 40 is placed closer to the center of the substrate 20 with respect to the positions at which the ball-like bodies 31 provided on the pressing body 30 are brought into contact with the substrate 20. With this, when force is applied by the pressing body 30 to the rear surface of the substrate 20, deflection of the center portion of the substrate 20 due to its own weight is suppressed by “the principle of leverage” with the support body 40 being the fulcrum. This may reduce pressing force necessary for causing the substrate 20 and the mask 10 to be in a horizontal state.

In the support body 40 in the above description, a member to be brought into contact with the mask 10 is a member having a round shape in cross section as an example, but the present invention is not limited thereto. Any structure having a basic function capable of supporting, or further, lifting up a selected area may be employed, and it is desired that the structure have a curved surface which is to be brought into contact with the mask 10 so as not to damage the substrate 20 or the mask 10. Further, in order to prevent damage to the mask 10 at the positions at which the support body 40 is brought into contact therewith, the thickness of the mask 10 may be locally increased at the positions.

Further, here, the support body 40 is brought into contact with the mask 10. Alternatively, a contact member may be brought into contact with the substrate 20. In the mask 10 used in this case, an aperture is formed in advance in the mask 10 at a portion at which the support body 40 is brought into contact with the substrate 20. Further, as the material of the support body 40, a metal, a resin, a glass, or the like may be appropriately used.

By the method described above, the substrate 20 and the mask 10 are caused to be in a horizontal state in a wide range, and the substrate 20 and the mask 10 are brought into intimate contact with each other without a gap. In this state, the multiple CCD cameras are used to measure the misalignment between the alignment marks of the substrate 20 and the mask 10, and confirm again that the accuracy of the misalignment is in the predetermined range. Note that, in a process step described with reference to FIG. 2 or FIG. 3, when the alignment error is outside the predetermined range, the substrate 20 and the pressing body 30 are returned to the initial state illustrated in FIG. 1 and the alignment step described above is carried out again.

Then, in the state in which the pressing body 30 presses the rear surface of the substrate 20 to bring the mask 10 into intimate contact with the surface on which a film is to be formed of the substrate 20, an evaporation source (not shown) provided below the mask 10 is used to evaporate an organic EL material onto the front surface of the substrate 20 via the mask 10 having the predetermined aperture pattern formed therein. Note that, when an organic EL thin film for color display is to be formed on the front surface of the substrate 20, masks 10 for red, green, and blue, respectively, are used and the alignment of the mask, the intimate contact between the mask and the substrate 20, and the film formation described above are carried out with regard to each of the masks.

In this way, the thin film pattern may be formed according to a predetermined mask aperture pattern. Further, a high-quality thin film pattern may be obtained which has no edge blur and the like caused by an evaporation material that enters through a gap between the mask 10 and the substrate 20.

### Example 1

Using the film formation apparatus illustrated in FIG. 5, organic EL display devices were manufactured on the glass substrate. In this example, a process step for forming the organic EL thin film according to the present invention is described. Note that, with regard to manufacturing process steps of the organic EL display devices other than that described below, publicly known process steps were used.

An organic EL material was loaded in an evaporation source (not shown) placed in the film formation apparatus, and the substrate 20 was located in the film formation apparatus so that the surface on which a film is to be formed thereof faced downward. The vacuum degree in the film formation apparatus was 2×10⁻⁴ Pa. As the substrate 20, a glass substrate formed of alkali-free glass having a thickness of 0.5 mm and the size of 400 mm (X)×500 mm (Y) was used. The substrate 20 had multiple arranged thin film transistors (TFTs) and electrode wiring formed thereon. The size of each of pixels arranged in the display region was 30 μm (Y)×120 μm (X), and the size of the display region of each of the organic EL display devices including multiple such pixels was 60 mm (X)×70 mm (Y). In the substrate 20, 25 display devices described above were placed so as to form a matrix of 5 rows×5 columns correspondingly to the aperture regions 12 illustrated in FIG. 5.

The mask 10 had a thickness of 40 μm and the size of 460 mm (X)×560 mm (Y), and was fixed by welding under tension to the mask frame 11. The mask frame 11 had a thickness of 20 mm and the width of the region inside the mask frame 11 was 396 mm (X)×496 mm (Y). The tension in the X direction as the long side direction of the apertures in the mask 10 was adjusted to be 1.5 times as large as that in the Y direction. An Invar material was used as the mask 10 and the mask frame 11. Further, in the aperture regions 12 of the mask 10, multiple apertures in which the dimension in the X direction was 60 mm and the dimension in the Y direction was 30 μm were provided.

The pressing body 30 was adapted to apply pressing force by means of ball-like rotating bodies using the elastic body. As the ball-like rotating bodies, the ball-like bodies 31 formed of SUS304 and having a diameter of 10 mm were used, and, as the elastic body, a spring formed of SUS304 was used. The strength of the spring was selected so that the spring might apply pressing force of about 0.196 N (20 gf) when the ball-like bodies 31 pressed the substrate 20 in the film formation. Such ball-like bodies 31 were placed at 20 locations in the region inside the mask frame 11 with the same pitches as those of the mask apertures as illustrated in FIG. 5. Note that, the distances Tx and Ty between the ball-like bodies 31 were 380 mm and 480 mm, respectively. Note that, the ratio of the pressing force in the X direction to the pressing force in the Y direction of the pressing body 30 (Y/X) was about 1.2.

Next, a process step of forming the organic EL material is described. First, in the previous process step, pixel electrodes electrically connected to driving TFTs were formed at positions corresponding to the pixel regions on the substrate 20, respectively. The alignment marks were simultaneously formed in the layer in which the pixel electrodes were formed.

Then, in the film formation apparatus, the above-mentioned mask 10 was aligned with predetermined pixels in the panel. After that, the organic EL material was formed. Note that, in the following, a process step of forming the organic EL material is described, but a similar method may be used to form a film of other materials forming an organic EL element.

First, from the state illustrated in FIG. 1, the moving mechanism was driven to lower the glass substrate supported by the substrate support member to approach the mask 10 until the distance between the substrate 20 and the mask 10 was 0.1 mm. In this state, the mask 10 and the substrate 20 deflected with their center portions being at the lowest level due to their own weights, but the mask 10 and the substrate 20 were not in contact with each other. Then, the multiple CCD cameras (not shown) were used to recognize the images of the respective alignment marks formed on the substrate 20 and the mask 10, and the substrate position controller coupled to the substrate support member was driven so that the relative positional error between the alignment marks was ±2 μm or smaller.

After the above-mentioned alignment was completed, as illustrated in FIG. 2, the substrate 20 was further lowered toward the mask 10 and the front surface of the substrate 20 was brought into contact with the mask 10. After the contact, the multiple CCD cameras were used to measure the misalignment between the alignment marks of the substrate 20 and the mask 10, and confirm that the accuracy was in a predetermined range. In this state, the pressing body 30 stood still above the rear surface of the substrate 20.

After that, as illustrated in FIG. 3, the pressing body 30 was lowered to be brought into contact with the rear surface of the substrate 20. Here, the ball-like bodies 31, which protruded from the pressing body 30 toward the substrate 20, pressed the rear surface of the substrate 20 along the four sides of the rear surface of the substrate 20. As a result, reaction force was generated in the substrate 20 and the mask 10, and the substrate 20 and the mask 10 were lifted up, and hence the substrate 20 and the mask 10 were caused to be in a substantially horizontal state in a wide range from the center portions toward the peripheries thereof. In this state, the multiple CCD cameras were used to measure the misalignment between the alignment marks of the substrate 20 and the mask 10, and confirm again that the accuracy of the misalignment was in the predetermined range.

With the pressing body 30 pressing the rear surface of the substrate 20, the gap between the surface on which a film was to be formed of the substrate 20 and the mask was 10 μm or smaller. In this way, with the mask 10 being in intimate contact with the surface on which a film was to be formed of the substrate 20, the organic EL material was evaporated onto the front surface of the substrate 20 via the mask 10 from the evaporation source provided below the mask 10. After the evaporation, the shape of the organic EL thin film formed on the substrate 20 at a thickness of about 50 nm was investigated. The width of the film formed was almost equal to the mask aperture width and no edge blur was observed. Further, it was confirmed that the organic EL material did not enter a pixel placed adjacently.

In the organic EL display device manufactured by the film forming process step described above, lack of a pixel due to light emission failure and a malfunction were not observed.

### Example 2

The ball-like bodies 31 were placed at positions along the long sides of the substrate 20 (in the Y direction) as illustrated in FIG. 8, and the pressing force applied when the ball-like bodies 31 were brought into contact with the substrate 20 was set to 0.294 N (30 gf). The mask 10 had a thickness of 40 μm and the size of 460 mm (X)×560 mm (Y), and was fixed by welding under tension to the mask frame 11 along the Y direction. The mask frame 11 had a thickness of 20 mm and the width of the region inside the mask frame 11 was 396 mm (X)×496 mm (Y). Accordingly, the tension was applied only in the X direction as the long side direction of the apertures in the mask 10. Note that, an Invar material was used as the mask 10 and the mask frame 11. Further, in each of the aperture regions 12 of the mask 10, multiple apertures in which the dimension in the X direction was 60 mm and the dimension in the Y direction was 30 μm were provided. The evaporation process step was carried out similarly to the case of Example 1 except for the above-mentioned points. Here, with the pressing body 30 pressing the rear surface of the substrate 20, the gap between the surface on which a film was to be formed of the substrate 20 and the mask was 10 μm or smaller.

After the evaporation, the shape of the organic EL thin film formed on the substrate 20 at a thickness of about 50 nm was investigated. The width of the film formed was almost equal to the mask aperture width and no edge blur was observed. Further, it was confirmed that the organic EL material did not enter a pixel placed adjacently.

In the organic EL display device manufactured by the film forming process step described above, lack of a pixel due to light emission failure and a malfunction were not observed.

### Example 3

The evaporation process step was carried out similarly to the case of Example 1 except that the support body 40 illustrated in FIG. 4 was used. The positions at which the support bodies 40 gave support were set inside the ball-like bodies 31 of the pressing body 30, and the support bodies 40 were placed at 20 locations within the plane of the substrate 20 correspondingly to the ball-like bodies 31. Note that, the support bodies 40 were located in the vicinity of the mask frame 11 so as not to hinder film formation in evaporation regions corresponding to the aperture regions 12. At locations at which the support bodies 40 described above were brought into contact with the substrate 20, ball-like bodies 41 formed of SUS304 and having a diameter of 10 mm were used. As the elastic body, a spring formed of SUS304 was used. The strength of the spring was selected so that the spring might apply an upward external force of about 0.196N (20 gf) when the ball-like bodies 41 were brought into contact with the mask 10 in the film formation.

Next, a process step of forming the organic EL material is described.

Similarly to the case of Example 1, the misalignment between the alignment marks of the mask 10 and the substrate 20 was measured and adjusted to ±2 μm or smaller. After that, the substrate 20 was further lowered toward the mask 10 and the front surface of the substrate 20 was brought into contact with the mask 10. After the contact, the multiple CCD cameras were used to measure the misalignment between the alignment marks of the substrate 20 and the mask 10, and confirm that the accuracy was ±2 μm or smaller. In this state, the pressing body 30 stood still above the rear surface of the glass substrate 20. Further, the support bodies 40 stood still below the surface on which a film was to be formed of the substrate 20.

After that, the support bodies 40 was raised and was stopped in a state of being in contact with the mask 10. Further, the pressing body 30 was lowered to press the rear surface of the substrate 20 to be put into the state illustrated in FIG. 4. Here, the ball-like bodies 31, which protruded from the pressing body 30 toward the substrate 20, pressed the rear surface of the substrate 20 along the four sides of the rear surface of the substrate 20. Further, the support bodies 40 gave support by means of the ball-like bodies 41 at the tips thereof pushing up the mask 10 and the substrate 20 along the four sides of the substrate 20. In this state, the multiple CCD cameras were used to measure the misalignment between the alignment marks of the substrate 20 and the mask 10, and confirm again that the accuracy of the misalignment was in the predetermined range.

As described above, in this example, by using both the support bodies 40 and the pressing body 30, deflection of the center portion of the substrate 20 due to its own weight was able to be suppressed. With this, the substrate 20 and the mask 10 were able to be caused in a substantially horizontal state.

Next, the pressing body 30 was caused to press the rear surface of the substrate 20, and the support bodies 40 supported the mask 10, so that the gap between the surface on which a film was to be formed of the substrate 20 and the mask was 10 μm or smaller. In this way, with the mask 10 being in intimate contact with the surface of the substrate 20, the organic EL material was evaporated onto the front surface of the substrate 20 via the mask 10 from the evaporation source provided below the mask 10.

After the evaporation, the shape of the organic EL thin film formed on the substrate 20 at a thickness of about 50 nm was investigated. The width of the film formed was almost equal to the mask aperture width and no edge blur was observed. Further, it was confirmed that the organic EL material did not enter a pixel placed adjacently.

In the organic EL display device manufactured by the film forming process step described above, lack of a pixel due to light emission failure and a malfunction were not observed.

### Example 4

A pressing body including structures 32 elongated along the directions of the sides of the substrate as illustrated in FIG. 12 was used. The pressing forces of the respective structures 32 were adjustable independently. The mask 10 had a thickness of 40 μm and the size of 460 mm (X)×560 mm (Y), and was fixed by welding under tension to the mask frame 11. The mask frame 11 had a thickness of 20 mm and the width of the region inside the mask frame 11 was 396 mm (X)×496 mm (Y). The tension in the X direction as the long side direction of the apertures in the mask 10 was adjusted to be 1.5 times as large as that in the Y direction. An Invar material was used as the mask 10 and the mask frame 11. Further, in the aperture regions 12 of the mask 10, multiple apertures in which the dimension in the X direction was 60 mm and the dimension in the Y direction was 30 μm were provided. The pressing force of the structures 32 along the Y direction perpendicular to the X direction in which the tension on the mask was at the maximum was adjusted to be 1.4 times as large as that of the structures 32 along the X direction. The evaporation process step was carried out otherwise similarly to the case of Example 1. Here, with the structures 32 pressing the rear surface of the substrate 20, the gap between the surface of the substrate 20 on which a film was to be formed and the mask was 5 μm or smaller.

After the evaporation, the shape of the organic EL thin film formed on the substrate 20 at a thickness of about 50 nm was investigated. The width of the film formed was almost equal to the mask aperture width and no edge blur was observed. Further, it was confirmed that the organic EL material did not enter a pixel placed adjacently.

In the organic EL display device manufactured by the film forming process step described above, lack of a pixel due to light emission failure and a malfunction were not observed.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-240759, filed Oct. 27, 2010, which is hereby incorporated by reference herein in its entirety.

What is claimed is:

1. A method for forming a film on a surface substrate on which a film is to be formed, via a mask including therein multiple apertures, in a manner that the mask is fixed to a mask frame under tension at least in one direction and the mask is brought into intimate contact with the substrate surface on which a film is to be formed, the substrate being placed above the mask, the method comprising:
aligning the mask and the substrate;
bringing a front surface of the substrate into contact with the mask; and
pressing the substrate from a rear surface side of the substrate in lines along at least two opposing sides of the substrate at least in a region inside the mask frame.

2. The method according to claim 1, further comprising, after the bringing a front surface of the substrate into contact with the mask and before the pressing the substrate from a rear surface side of the substrate,
supporting the substrate from a side of the surface on which a film is to be formed, at a position closer to a center of the substrate with respect to a position at which the substrate is pressed from the rear surface side of the substrate.

3. The method according to claim 1, wherein, when the mask is applied with tension in a first direction along two opposing sides of the substrate which is larger than tension applied in a second direction along two opposing sides other than the two opposing sides,
in the pressing the substrate from the rear surface side of the substrate,
a pressing force applied in lines along the second direction from the rear surface side of the substrate is larger than a pressing force applied in lines along the first direction from the rear surface side of the substrate.

4. A film formation apparatus, comprising:
a mask holder for holding a mask frame to which a mask is fixed under tension;
a substrate support member for holding a substrate above the mask, with a substrate surface on which a film is to be formed facing on the mask; and
a pressing body for pressing the substrate from a rear surface side in lines along at least two opposing sides of the substrate at least in a region inside the mask frame.

5. The film formation apparatus according to claim 4, further comprising a support body for supporting the substrate from a side of the substrate surface on which a film is to be formed.
